(19) United States
(12) Patent Application Publication
(10) Pub. No.: US 2019/0181067 A1
(43) Pub. Date: Jun. 13, 2019

(54) SEMICONDUCTOR PACKAGE AND METHOD OF FABRICATING THE SAME

(71) Applicant: SAMSUNG ELECTRONICS CO., LTD., Suwon-si (KR)

(72) Inventor: Soon Bum KIM, Suwon-si (KR)

(21) Appl. No.: 16/001,181

(22) Filed: Jun. 6, 2018

(30) Foreign Application Priority Data
Dec. 13, 2017 (KR) 10-2017-0171520

(51) Int. Cl. H01L 23/31; H01L 23/532; H01L 23/498; H05K 3/40; B23K 3/06

(52) U.S. Cl. CPC H01L 23/3114; H01L 23/53238; B23K 3/0623; H05K 3/4015; H01L 23/49816

(57) ABSTRACT

A semiconductor package includes a semiconductor substrate, a first conductive pattern on the semiconductor substrate, a top surface of the first conductive pattern including a first inclined surface and a second inclined surface that are inclined with respect to a top surface of the semiconductor substrate, and a distance between the first and second inclined surfaces decreasing away from the top surface of the semiconductor substrate, a second conductive pattern extending along the top surface of the first conductive pattern; and a solder ball disposed on the second conductive pattern.

### CROSS-REFERENCE TO RELATED APPLICATION

Korean Patent Application No. 10-2017-0171520, filed on Dec. 13, 2017, in the Korean Intellectual Property Office, and entitled: “Semiconductor Package and Method of Fabricating The Same,” is incorporated by reference herein in its entirety.

### BACKGROUND

### 1. Field

Embodiments relate to a semiconductor package and a method of fabricating the same.

### 2. Description of the Related Art

Flip chip bonding may be used, instead of wire bonding, to mount semiconductor chips on a substrate for a package. As semiconductor integrated circuits (ICs), which are used in electronic devices, have become highly dense and integrated, the electrode terminals of semiconductor chips may be provided with more pins and finer pitches.

### SUMMARY

Embodiments are directed to a semiconductor package, including a semiconductor substrate, a first conductive pattern on the semiconductor substrate, a top surface of the first conductive pattern including a first inclined surface and a second inclined surface that are inclined with respect to a top surface of the semiconductor substrate, and a distance between the first and second inclined surfaces decreasing away from the top surface of the semiconductor substrate, a second conductive pattern extending along the top surface of the first conductive pattern; and a solder ball disposed on the second conductive pattern.

Embodiments are also directed to a semiconductor package, including a semiconductor substrate, a first conductive pattern on the semiconductor substrate, the first conductive pattern having a top surface that includes a first inclined surface and a second inclined surface that are inclined with respect to a top surface of the semiconductor substrate, a second conductive pattern on the first conductive pattern, the second conductive pattern including a first protruding portion, which extends along the first inclined surface, and a second protruding portion, which extends along the second inclined surface, a width of the first protruding portion and a width of the second protruding portion increasing away from the top surface of the semiconductor substrate, and a solder ball on the second conductive pattern.

Embodiments are also directed to a semiconductor package, including a substrate for the semiconductor package, a chip bump disposed on the substrate, a semiconductor chip disposed on the chip bump, and a first mold film disposed between the substrate and the semiconductor chip and surrounding the chip bump. The chip bump may include a first conductive pattern, which is in contact with the semiconductor chip, a solder ball, which is in contact with the substrate, and a second conductive pattern, which is between the first conductive pattern and the solder ball, and a distance between a bottom surface of the first conductive pattern and a bottom surface of the second conductive pattern may decrease away from the first mold film.

### BRIEF DESCRIPTION OF THE DRAWINGS

Features will become apparent to those of skill in the art by describing in detail example embodiments with reference to the attached drawings in which:

FIG. 1 illustrates a cross-sectional view of chip bumps of a semiconductor package according to some example embodiments of the present disclosure.

FIGS. 2 through 8 illustrate enlarged views of a first region R1 for explaining various shapes of chip bumps.

FIG. 9 illustrates a cross-sectional view of a semiconductor package according to some example embodiments of the present disclosure.

FIG. 10 illustrates an enlarged view of a second region R2 of FIG. 9.

FIGS. 11 through 21 illustrate stages in a method of fabricating a semiconductor package according to some example embodiments of the present disclosure.

FIGS. 22 through 27 illustrate stages in a method of fabricating a semiconductor package according to some example embodiments of the present disclosure.

### DETAILED DESCRIPTION

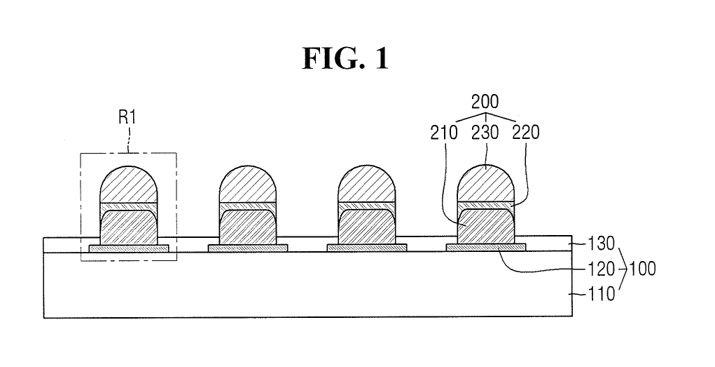

Chip bumps of a semiconductor package according to some example embodiments of the present disclosure will hereinafter be described with reference to FIGS. 1 through 8.

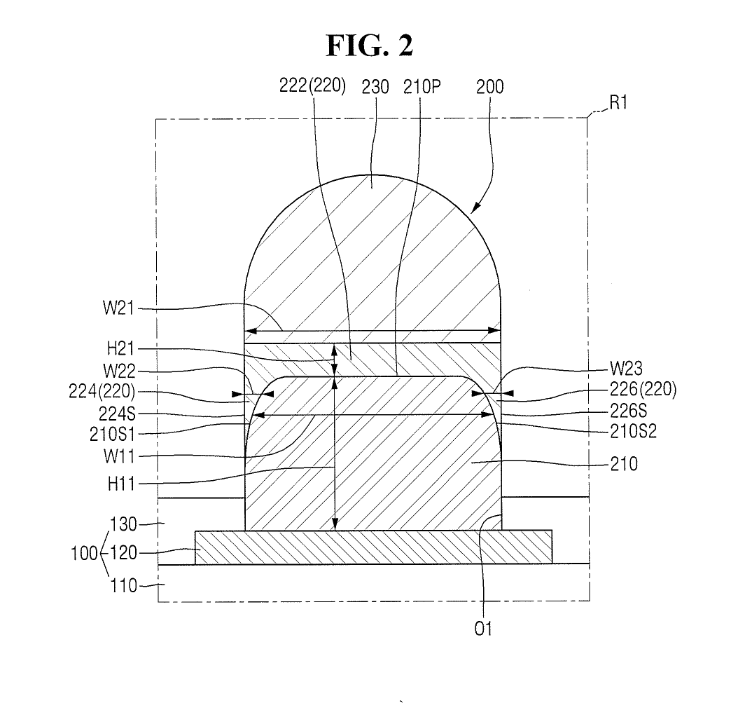

FIG. 1 is a cross-sectional view illustrating chip bumps of a semiconductor package according to some example embodiments of the present disclosure. FIGS. 2 through 8 are enlarged views of a first region R1 for explaining various shapes of chip bumps.

Referring to FIGS. 1 and 2, the semiconductor package according to some example embodiments of the present disclosure includes a semiconductor chip 100 and at least one chip bump 200.

The semiconductor chip 100 may include a semiconductor substrate 110, at least one chip pad 120, and a chip insulating film 130. The semiconductor chip 100 may be, for example, a logic element such as a micro-processor, etc.

The chip pad 120 may be, for example, formed on the semiconductor substrate 110. A plurality of chip pads 120 may be formed on the semiconductor substrate 110. The chip pad 120 may include a conductive material. The chip pad 120 may be electrically connected to electric circuitry formed in the semiconductor substrate 110, such as a circuit pattern.

The chip insulating film 130 may be formed on the semiconductor substrate 110 and on the chip pad 120. The chip insulating film 130 may partially expose the chip pad 120. For example, the chip insulating film 130 may include a first opening OP1, which exposes part of the top surface of the chip pad 120.

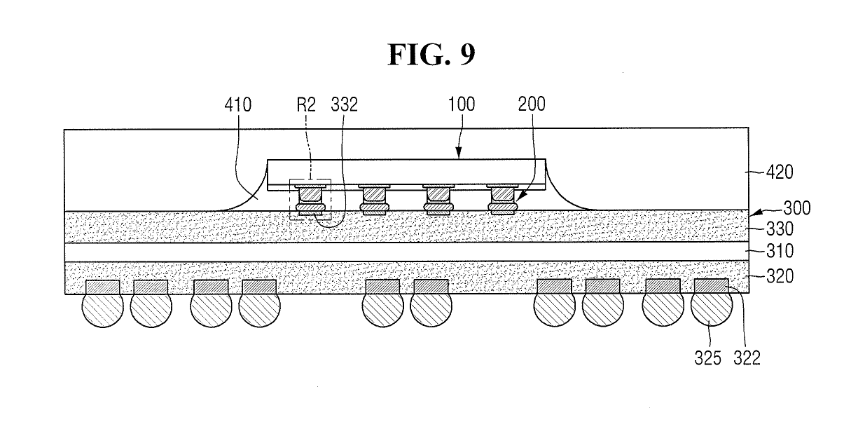

The chip bump 200 may be formed on the semiconductor chip 100. The chip bump 200 may be used as, for example, a conductive protrusion for mounting the semiconductor chip 100 on a substrate for a package. For example, the chip bump 200 may be used as a conductive protrusion for tape-automated-bonding (TAB) or flip-chip-bonding the semiconductor chip 100 on a substrate (300 of FIG. 9) for a package. In another implementation, the chip bump 200 may be used as a conductive protrusion for directly connecting a ball grid array (BGA) or a chip scale package (CSP) on a substrate for a package.

The chip bump 200 may include a first conductive pattern 210, a second conductive pattern 220, and a first solder ball 230.

The first conductive pattern 210 may be formed on the semiconductor substrate 110. For example, the first conductive pattern 210 may fill a first opening O1. The first conductive pattern 210 may be in contact with a chip pad 120. The first conductive pattern 210 may be, for example, pillar-shaped.

The upper width of the first conductive pattern 210 may decrease away from the top surface of the semiconductor substrate 110. For example, the top surface of the first conductive pattern 210 may include first and second inclined surfaces 210S1 and 210S2, which are inclined with respect to the top surface of the semiconductor substrate 110. The first and second inclined surfaces 210S1 and 21052 may be parts of the top surface of the first conductive pattern 210 that extend from both sidewalls of the first conductive pattern 210. The distance between the first and second inclined surfaces 210S1 and 210S2, i.e., a first width W11, may decrease away from the top surface of the semiconductor substrate 110.

In some example embodiments, the first and second inclined surfaces 210S1 and 210S2 may be upwardly convex.

In some example embodiments, the height of the first conductive pattern 210 may increase away from both sidewalls of the first conductive pattern 210. For example, the distance between the bottom surface of the first conductive pattern 210 and the bottom surface of the second conductive pattern 220, i.e., a first height H11, may increase away from both sidewalls of the first conductive pattern 210.

In some example embodiments, the top surface of the first conductive pattern 210 may further include a flat surface 210P, which is disposed between the first and second inclined surfaces 210S1 and 210S2. The flat surface 210P of the first conductive pattern 210 may be substantially parallel to the top surface of the semiconductor substrate 110. Accordingly, as illustrated in FIG. 2, an upper portion of the first conductive pattern 210 may have a trapezoidal cross-sectional shape.

The first conductive pattern 210 may include a material with a high electrical conductivity. The first conductive pattern 210 may include, for example, copper (Cu). In an implementation, the first conductive pattern 210 may be predominantly copper.

The second conductive pattern 220 may be formed on the first conductive pattern 210. For example, the second conductive pattern 220 may extend along the top surface of the first conductive pattern 210.

The width of the top surface of the second conductive pattern 220, i.e., a second width W21, may be larger than the first width W11 of the first conductive pattern 210. For example, the second conductive pattern 220 may include a flat portion 222, a first protruding portion 224, and a second protruding portion 226.

The first protruding portion 224 may be part of the second conductive pattern 220 that extends along the first inclined surface 210S1 of the first conductive pattern 210. The width of the first protruding portion 224 may increase away from the top surface of the semiconductor substrate 110. For example, the distance between a first outer sidewall 224S of the first protruding portion 224 and the first inclined surface 210S1, i.e., a third width W22, may increase away from the top surface of the semiconductor substrate 110.

The second protruding portion 226 may be part of the second conductive pattern 220 that extends along the second inclined surface 21052 of the first conductive pattern 210. The width of the second protruding portion 226, like the width of the first protruding portion 224, may increase away from the top surface of the semiconductor substrate 110. For example, the distance between a second outer sidewall 226S of the second protruding portion 226 and the second inclined surface 210S2, i.e., a fourth width W23, may increase away from the top surface of the semiconductor substrate 110.

FIG. 2 illustrates an example in which the first and second protruding portion 224 and 226 are symmetrical with each other. For example, on a given level, the third width W22 of the first protruding portion 224 and the fourth width W23 of the second protruding portion 226 may differ from each other.

The flat portion 222 may be part of the second conductive pattern 220 that connects the first and second protruding portions 224 and 226. For example, the first and second protruding portions 224 and 226 may extend downwardly from both ends of the flat portion 222.

In some example embodiments, the top surface of the flat portion 222 may be substantially parallel to the top surface of the semiconductor substrate 110.

In some example embodiments, the sidewalls of the first conductive pattern 210 and the outer sidewalls of the second conductive pattern 220 may be disposed substantially on the same plane. As used herein, the term “same” not only means that elements are completely identical, but also means that there are slight differences between the elements that may be generated due to process margins. For example, the first outer sidewall 224S of the first protruding portion 224 may be disposed on the same plane as one sidewall of the first conductive pattern 210, and the second outer sidewall 226S of the second protruding portion 226 may be disposed on the same plane as the other sidewall of the first conductive pattern 210.

In some example embodiments, the height of the second conductive pattern 220 may decrease away from both sidewalls of the second conductive pattern 220. For example, the distance between the top surface of the first conductive pattern 210 and the top surface of the second conductive pattern 220, i.e., a second height H21, may decrease away from both sidewalls of the second conductive pattern 220.

The second conductive pattern 220 may include a material with a low wettability with the first solder ball 230. In some example embodiments, a wettability of the second conductive pattern 220 with the first solder ball 230 may be lower than a wettability of the first conductive pattern 210 with the solder ball 230. In an implementation, the second conductive pattern 220 may include a material that is different from either of the material of the first conductive pattern 210 and the material of the first solder ball 230. The second conductive pattern 220 may include, for example, nickel (Ni), tin (Sn), or an alloy thereof. In an implementation, the second conductive pattern 220 may be predominantly nickel or predominantly tin.

The first solder ball 230 may be formed on the second conductive pattern 220.

FIG. 2 illustrates an example in which the first solder ball 230 is semicircular in shape. The first solder ball 230 may have various shapes other than a semicircular shape. The width of the bottom surface of the first solder ball 230 and the width of the top surface of the second conductive pattern 220 are illustrated in FIG. 2 as being the same.

The first solder ball 230 may include a solder material. For example, the first solder ball 230 may include at least one of lead (Pb), Sn, indium (In), bismuth (Bi), antimony (Sb), silver (Ag), and an alloy thereof.

In general, in a case where the chip bump 200 includes Cu, the first solder ball 230 may flow down over the Cu surface of the chip bump 200. For example, in a soldering process for mounting the semiconductor chip 100 on the substrate 300 of FIG. 9, the first solder ball 230 may flow down over the Cu surface of the chip bump 200. As a result, the height of the first solder ball 230 may be reduced, thereby lowering the reliability of a bonding process. By comparison, the semiconductor package according to some example embodiments of the present disclosure may improve product reliability by using the second conductive pattern 220 having a low wettability with the first solder ball 230.

For example, the second conductive pattern 220 may cover the top surface of the first conductive pattern 210, which has the first and second inclined surfaces 210S1 and 21052. Thus, the second conductive pattern 220 may increase the distance between the sidewalls of the first conductive pattern 210 and the sidewalls of the first solder ball 230. Accordingly, the second conductive pattern 220 may prevent the first solder ball 230 from flowing down over the sidewalls of the first conductive pattern 210 during a soldering process.

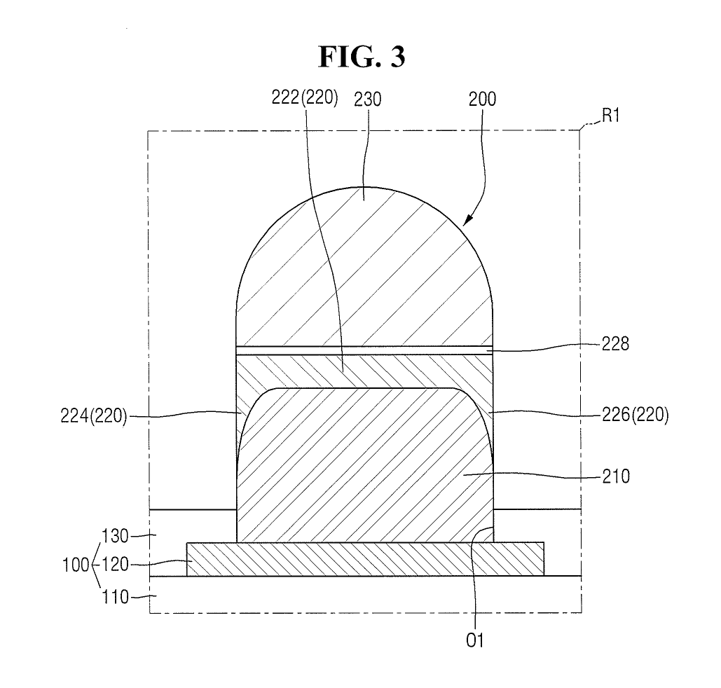

Referring to FIGS. 1 and 3, a chip bump 200 may further include an intermetallic compound (IMC) film 228.

The IMC film 228 may be interposed between the second conductive pattern 220 and the first solder ball 230. The intermetallic compound may be a material that is different from either of the material of the second conductive pattern 220 and the material of the first solder ball 230. The IMC film 228 may extend along the top surface of the second conductive pattern 220.

The IMC film 228 may include an IMC between the second conductive pattern 220 and the first solder ball 230 that is formed by, for example, a soldering process. For example, in a case where the second conductive pattern 220 includes Ni and the first solder ball 230 includes a solder material, the IMC film 228 may include a compound of Ni and the solder material.

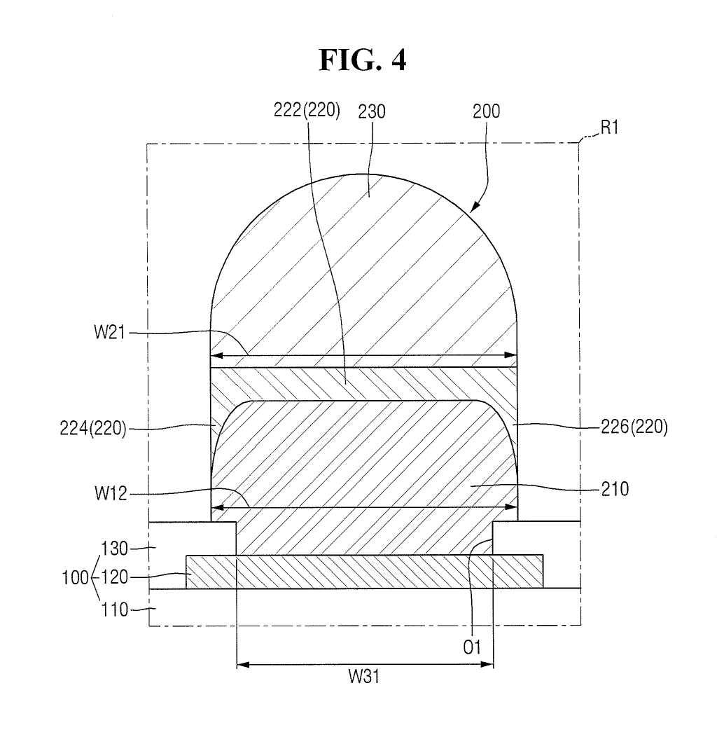

Referring to FIGS. 1 and 4, the width of at least part of a first conductive pattern 210 may be larger than the width of a first opening O1, which is formed in a chip insulating film 130.

For example, the distance between both sidewalls of the first conductive pattern 210, i.e., a fifth width W12, may be larger than a sixth width W31 of the first opening O1. The first conductive pattern 210 may fill the first opening O1, and the width of the bottom surface of the first conductive pattern 210 may be less than the fifth width W12 of the first conductive pattern 210.

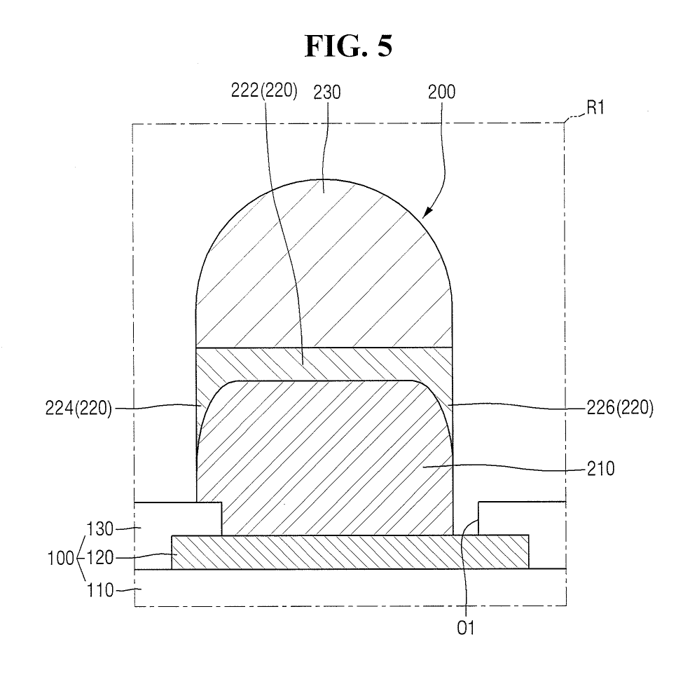

Referring to FIGS. 1 and 5, a first conductive pattern 210 may not completely fill a first opening O1, which is formed in a chip insulating film 130.

For example, at least one sidewall of the first conductive pattern 210 may not be placed in contact with a chip insulating film 130, for example, because of the characteristics of a process for forming a chip bump 200. Accordingly, the top surface of a chip pad 120 may be partially exposed.

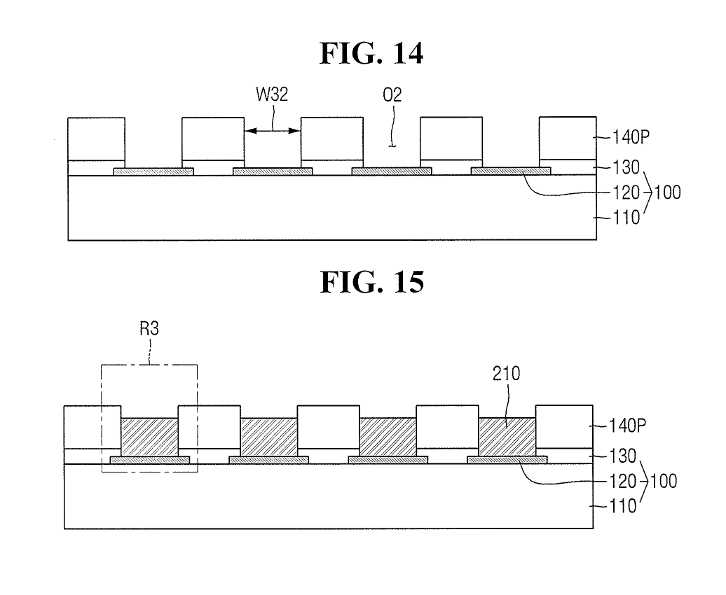

For example, the first conductive pattern 210 may not completely fill the first opening O1, which is formed in the chip insulating film 130, due to, for example, the misalignment of a resist pattern 140P of FIG. 14, which will be described below.

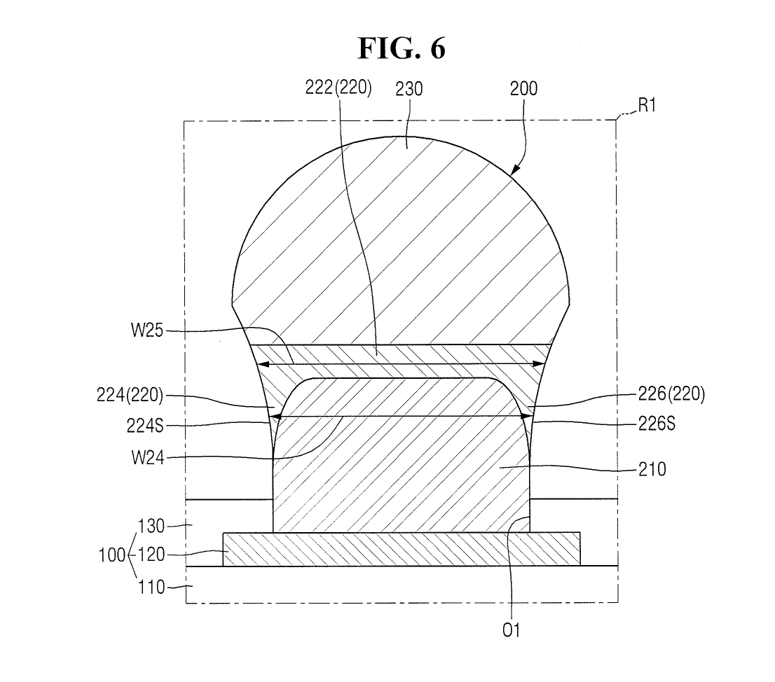

Referring to FIGS. 1 and 6, the width of a second conductive pattern 220 may increase away from the top surface of a semiconductor substrate 110.

For example, the distance between a first outer sidewall 224S of a first protruding portion 224 and a second outer sidewall 226S of a second protruding portion 226, i.e., a seventh width W24, may increase away from the top surface of the semiconductor substrate 110. Also, the distance between both sidewalls of a flat portion 222, i.e., an eighth width W25, may increase away from the top surface of the semiconductor substrate 110. The eighth width W25 of the second conductive pattern 220 may be larger than the seventh width W24 of the second conductive pattern 220.

Accordingly, a second conductive pattern 220 with a widened top surface may be provided. A chip bump 200 according to the example embodiment of FIG. 6 may prevent a first solder ball 230 from flowing down over the sidewalls of a first conductive pattern 210 and may widen the contact area between the second conductive pattern 220 and the first solder ball 230. Also, the chip bump 200 according to the example embodiment of FIG. 6 may improve electrical resistance by increasing the size of the first solder ball 230 formed on the second conductive pattern 220.

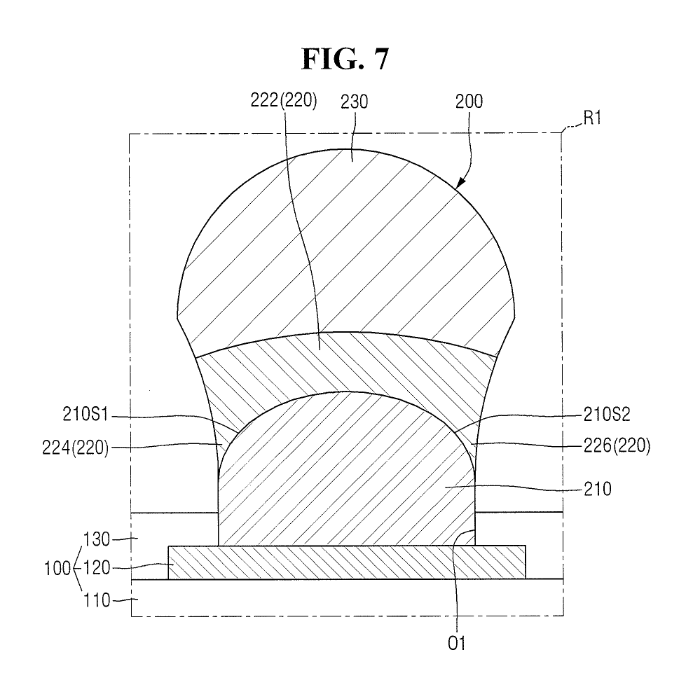

Referring to FIGS. 1 and 7, the top surface of a first conductive pattern 210 may be upwardly convex.

For example, the top surface of the first conductive pattern 210 may not include the flat surface 210P of FIG. 1. For example, the top surface of the first conductive pattern 210 may include first and second inclined surfaces 21051 and 210S2, which are both upwardly convex, and the first and second inclined surfaces 21051 and 210S2 may be connected to each other.

In some example embodiments, the top surface of a second conductive pattern 220, like the top surface of the first conductive pattern 210, may be upwardly convex. For example, the top surface of a flat portion 222 of the second conductive pattern 220 may be upwardly convex. However, in some example embodiments, the curvature radius of the top surface of the second conductive pattern 220 may be larger than the curvature radius of the top surface of the first conductive pattern 210.

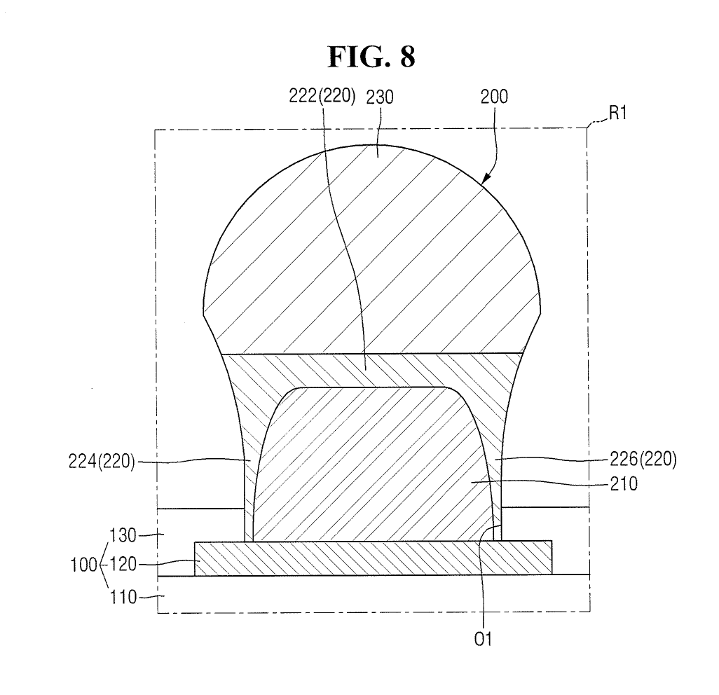

Referring to FIGS. 1 and 8, a second conductive pattern 220 may completely surround the top surface and the sidewalls of a first conductive pattern 210. For example, the first conductive pattern 210 may be completely surrounded by a chip pad 120 and the second conductive pattern 220.

In some example embodiments, the second conductive pattern 220 may be placed in contact with the chip pad 120 and a chip insulating film 130. For example, the first conductive pattern 210 may fill part of a first opening O1, and the second conductive pattern 220 may fill the rest of the first opening O1. Accordingly, first and second protruding portions 224 and 226 of the second conductive pattern 220 may extend over to the top surface of the chip pad 120. The lowermost surface of the first conductive pattern 210 and the lowermost surface of the second conductive pattern 220 may be disposed on the same plane.

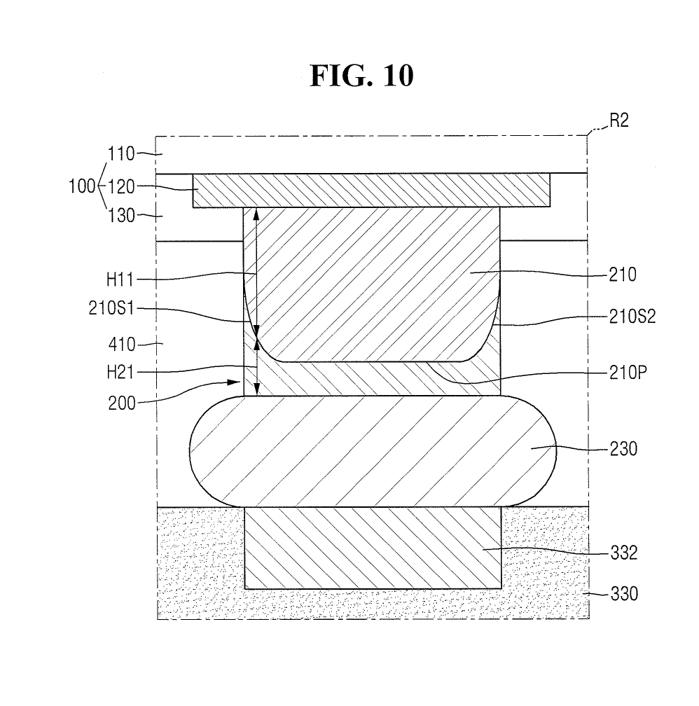

A semiconductor package according to some example embodiments of the present disclosure will hereinafter be described with reference to FIGS. 9 and 10.

FIG. 9 is a cross-sectional view of a semiconductor package according to some example embodiments of the present disclosure. FIG. 10 is an enlarged view of a second region R2 of FIG. 9. For convenience, any redundant descriptions of the example embodiments of FIGS. 1 through 8 will be omitted.

Referring to FIGS. 9 and 10, the semiconductor package according to some example embodiments of the present disclosure may further include a substrate 300 for a package.

The substrate 300 may be for example, a printed circuit board (PCB) or a ceramic substrate.

The substrate 300 may include a circuit pattern 310, a first insulating film 320, a second insulating film 330, at least one first connection pad 322, at least one second connection pad 332, at least one second solder ball 325, a first mold film 410, and a second mold film 420.

The circuit pattern 310 may form the electrical circuitry of the substrate 300. The first insulating film 320 may be formed above the circuit pattern 310, and the second insulating film 330 may be formed below the circuit pattern 310.

The first connection pad 322 may be formed in the first insulating film 320. The first connection pad 322 may be connected to electric circuitry formed in the substrate 300, such as the circuit pattern 310. Thus, the first connection pad 322 may be part of the circuit pattern 310 of the substrate 300 that is connected to the outside.

For example, the first connection pad 322 may be connected to the second solder ball 325. Accordingly, the substrate 300 may be electrically connected to another substrate via the second solder ball 325. For example, the substrate 300 may be electrically connected to another substrate for a package via the second solder ball 325. Thus, in another example, the substrate 300 may be electrically connected to, for example, a module board or a main circuit board via the second solder ball 325.

The second connection pad 332 may be formed in the second insulating film 330. The second connection pad 332 may be electrically connected to another substrate via the second solder ball 325. For example, the substrate 300 may be electrically connected to another substrate for a package via the second solder ball 325. Thus, in another example, the substrate 300 may be electrically connected to, for example, a module board or a main circuit board via the second solder ball 325.

The second connection pad 332 may be formed in the second insulating film 330. The second connection pad 332 may be connected to electric circuitry formed in the substrate 300, such as the circuit pattern 310. Thus, the second connection pad 332 may be part of the circuit pattern 310 of the substrate 300 that is connected to the outside.

A semiconductor chip 100 may be mounted on the substrate 300. For example, the semiconductor chip 100 may be mounted on the substrate 300 through flip chip bonding.

At least one chip bump 200 may be disposed between the semiconductor chip 100 and the substrate 300 and may electrically connect the semiconductor chip 100 and the substrate 300. For example, referring to FIG. 10, a first conductive pattern 210 of the chip bump 200 may be connected to the chip pad 120 of the semiconductor chip 100, and a first solder ball 230 of the chip bump 200 may be connected to the second connection pad 332 of the substrate 300.

The first mold film 410 may be disposed between the semiconductor chip 100 and the substrate 300 and may surround the chip bump 200. Accordingly, the first mold film 410 may protect the chip bump 200.

The second mold film 420 may be formed on the substrate 300. The second mold film 420 may surround the semiconductor chip 100 and the first mold film 410. Accordingly, the second mold film 420 may protect the semiconductor chip 100.

FIG. 9 illustrates an example in which the second mold film 420 covers the top surface of the semiconductor chip 100. Thus, in another example, the second mold film 420 may cover the sidewalls of the semiconductor chip 100 and may expose the top surface of the semiconductor chip 100.

The first and second mold films 410 and 420 may include, for example, an epoxy molding compound (EMC) or polyimide (PI).

Referring again to FIG. 10, the first mold film 410 may surround the chip bump 200. Thus, the height of the first conductive pattern 210 may increase away from the first mold film 410. For example, the distance between the top surface of the first conductive pattern 210 and the top surface of the second conductive pattern 220, i.e., a first height H11, may increase away from the first mold film 410.

On the other hand, the height of the second conductive pattern 220 may decrease away from the first mold film 410. For example, the distance between the bottom surface of the first conductive pattern 210 and the bottom surface of the second conductive pattern 220, i.e., a second height H21, may decrease away from the first mold film 410.

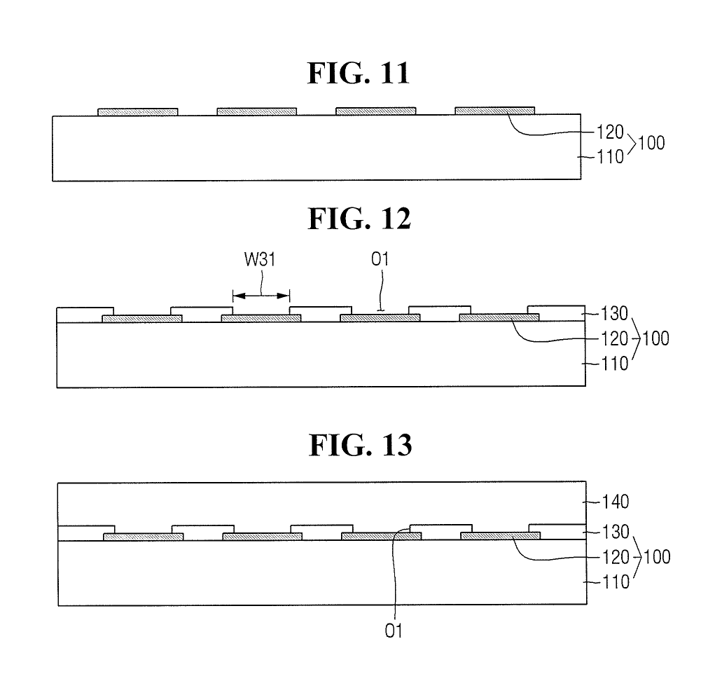

A method of fabricating a semiconductor package according to some example embodiments of the present disclosure will hereinafter be described with reference to FIGS. 11 through 21.

FIGS. 11 through 21 illustrate intermediate steps of a method of fabricating a semiconductor package according to some example embodiments of the present disclosure. For clarity, any redundant descriptions of the example embodiments of FIGS. 1 through 10 may be omitted.

Referring to FIG. 11, a semiconductor chip 100, which may include a semiconductor substrate 110 and one or more chip pads 120, is provided.

The chip pad 120 may be, for example, formed on the semiconductor substrate 110. The chip pad 120 may include a conductive material. The chip pad 120 may be electrically connected to electrical circuitry formed in the semiconductor substrate 110, such as a circuit pattern.

Referring to FIG. 12, a chip insulating film 130 is formed on the semiconductor substrate 110 and on the chip pad 120.

The chip insulating film 130 may partially expose the chip pad 120. For example, the chip insulating film 130 may include at least one first opening O1, which partially exposes the top surface of the chip pad 120. For example, a sixth width W31 of the first opening O1 may be less than the width of the chip pad 120. The first opening O1 may be, for example, formed by photolithography.

Referring to FIG. 13, a resist film 140 is formed on the chip pad 120 and on the chip insulating film 130. The resist film 140 is formed to fill the first opening O1.

The resist film 140 may include, for example, photosensitive photoresist.

Referring to FIG. 14, a resist pattern 140P is formed by patterning the resist film 140.

The resist pattern 140P may partially expose the chip pad 120. For example, the resist pattern 140P may include at least one second opening O2, which partially exposes the top surface of the chip pad 120. The second opening O2 may be, for example, formed by photolithography.

FIG. 14 illustrates an example in which a ninth width W32 of the second opening O2 is the same as the sixth width W31 of the first opening O1. Thus, in another example, the ninth width W32 of the second opening O2 may be larger than the sixth width W31 of the first opening O1.

Also, FIG. 14 illustrates an example in which the sidewalls of the chip insulating film 130 are aligned with the sidewalls of the resist pattern 140P. Thus, in another example, some of the sidewalls of the resist pattern 140P may be recessed from some of the sidewalls of the chip insulating film 130 so as to partially expose the top surface of the chip insulating film 130. In yet another example, some of the sidewalls of the resist pattern 140P may be projected from some of the sidewalls of the chip insulating film 130 so as to cover some of the sidewalls of the chip insulating film 130.

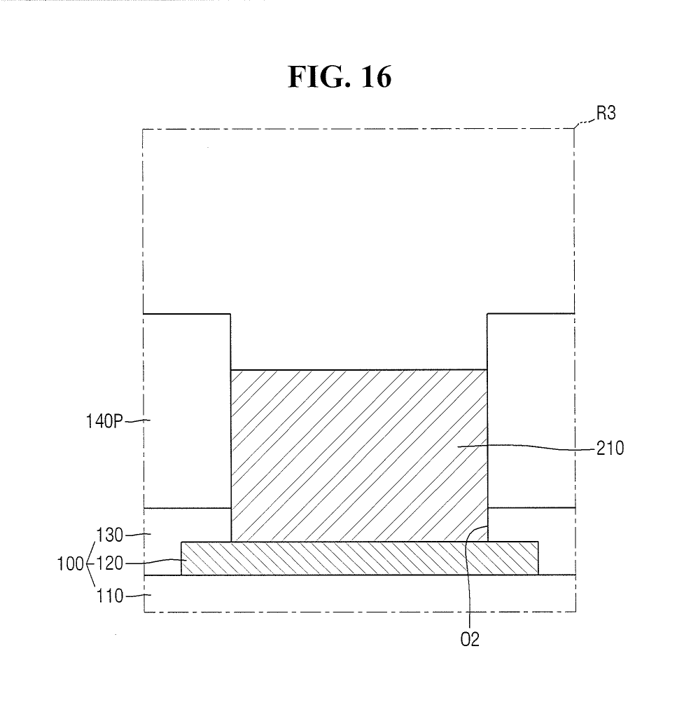

Referring to FIGS. 15 and 16, at least one first conductive pattern 210, which partially fills the second opening O2, is formed. For example, FIG. 16 is an enlarged view of a third region R3 of FIG. 15.

Accordingly, the first conductive pattern 210 may be formed on the chip pad 120 to be placed in contact with the chip pad 120. The first conductive pattern 210 may be formed to fill the second opening O2. Thus, the sidewalls of the first conductive pattern 210 may be defined by the sidewalls of the chip insulating film 130 or the sidewalls of the resist pattern 140P.

The first conductive pattern 210 may include, for example, Cu. For example, the first conductive pattern 210 may be formed through electroplating to include Cu.

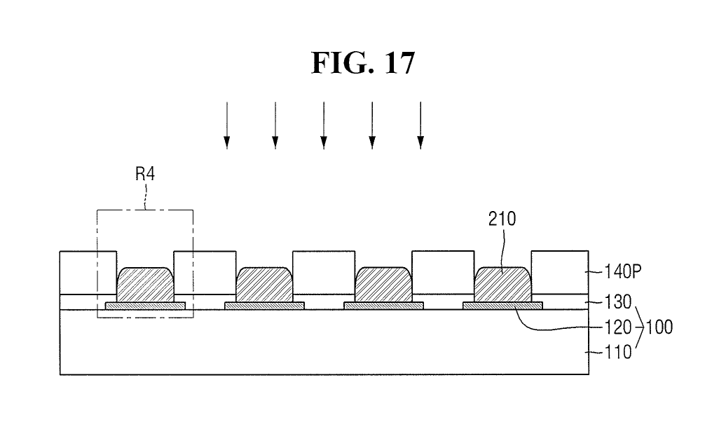

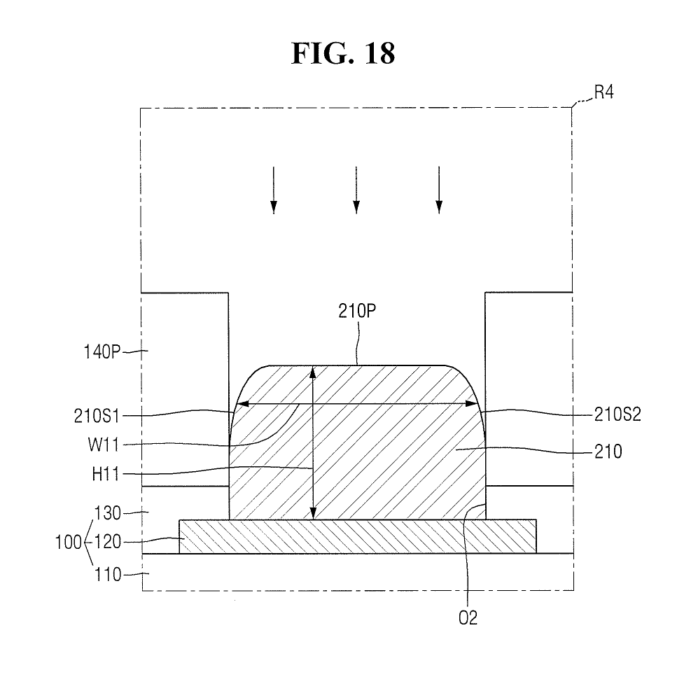

Referring to FIGS. 17 and 18, chemical etching is performed on the first conductive pattern 210. For example, FIG. 18 is an enlarged view of a fourth region R4 of FIG. 17.

For example, a chemical etching operation may be performed on the first conductive pattern 210 to selectively etch the first conductive pattern 210. For example, in a case where the first conductive pattern 210 includes Cu, the chemical etching operation may be performed using an etchant having a high etching selectivity to Cu.

During the chemical etching operation, the etchant may infiltrate into the boundaries between the first conductive pattern 210 and the resist pattern 140P. In this case, part of the upper portion of the first conductive pattern 210 that is adjacent to the resist pattern 140P may be intensively etched.

As a result, as illustrated in FIG. 18, the first conductive pattern 210 may be formed to have a width gradually decreasing away from the top surface of the semiconductor substrate 110. For example, the distance between first and second inclined surfaces 210S1 and 210S2 of the first conductive pattern 210, i.e., a first width W11, may decrease away from the top surface of the semiconductor substrate 110.

Also, the first conductive pattern 210 may be formed to have a height gradually increasing away from both sidewalls thereof. For example, the distance between the bottom surface of the first conductive pattern 210 and the top surface of a first conductive pattern 210, i.e., a first height H11, may increase away from both sidewalls of the first conductive pattern 210.

FIG. 18 illustrates an example in which the top surface of the first conductive pattern 210 includes a flat portion 222. Thus, in another example, the top surface of the first conductive pattern 210 may be upwardly convex depending on the characteristics of the chemical etching operation performed on the first conductive pattern 210.

Also, FIG. 18 illustrates an example in which the chip pad 120 is not exposed. Thus, in another example, the first conductive pattern 210 may be further etched to expose the chip pad 120 depending on the characteristics of the chemical etching operation performed on the first conductive pattern 210.

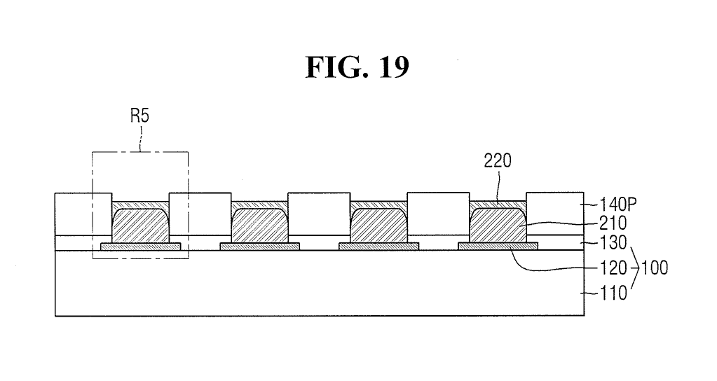

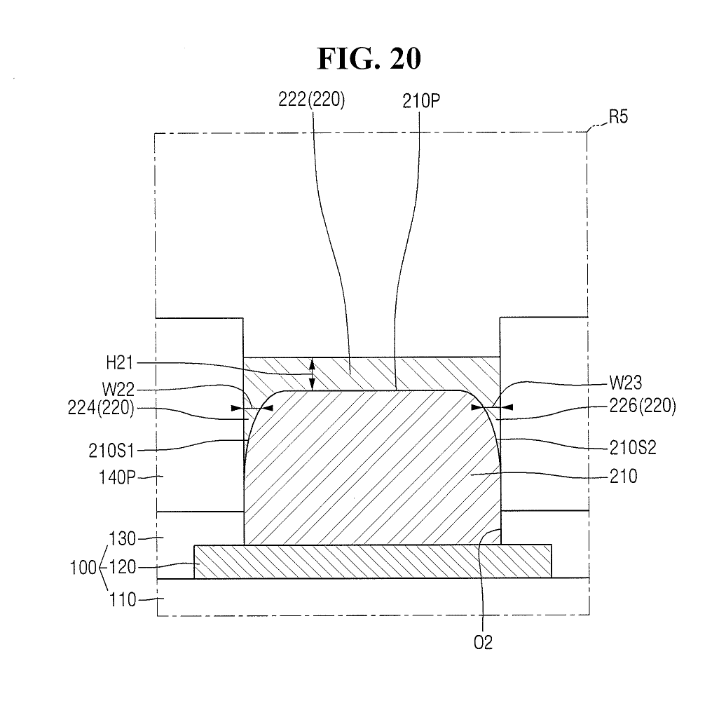

Referring to FIGS. 19 and 20, a second conductive pattern 220 is formed on the first conductive pattern 210. For example, FIG. 20 is an enlarged view of a fifth region R5 of FIG. 19.

For example, referring to FIG. 20, the second conductive pattern 220 may be formed to extend along the top surface of the first conductive pattern 210. Accordingly, the second conductive pattern 220 may be formed to include a first protruding portion 224, a second protruding portion 226, and a flat portion 222.

For example, the distance between a first outer sidewall 224S and a first inclined surface 210S1 of the first protruding portion 224, i.e., a third width W22, may increase away from the top surface of the semiconductor substrate 110.

For example, the distance between a second outer sidewall 226S and a second inclined surface 210S2 of the second protruding portion 226, i.e., a fourth width W23, may increase away from the top surface of the semiconductor substrate 110

In some example embodiments, the second conductive pattern 220 may be formed to fill part of the second opening O2 that is not filled with the first conductive pattern 210. Accordingly, the sidewalls of the second conductive pattern 220 may be defined by the sidewalls of the chip insulating film 130 or the sidewalls of the resist pattern 140P.

The second conductive pattern 220 may include a material with a low wettability with a first solder ball 230. For example, the second conductive pattern 220 may include at least one of Ni, Sn, and an alloy thereof. For example, the second conductive pattern 220 may be formed through electroplating to include Ni.

FIG. 20 illustrates an example in which the top surface of the flat portion 222 is substantially parallel to the top surface of the semiconductor substrate 110. Thus, the top surface of the flat portion 222 may be upwardly convex depending on the shape of the first conductive pattern 210 or the characteristics of electroplating performed for forming the second conductive pattern 220.

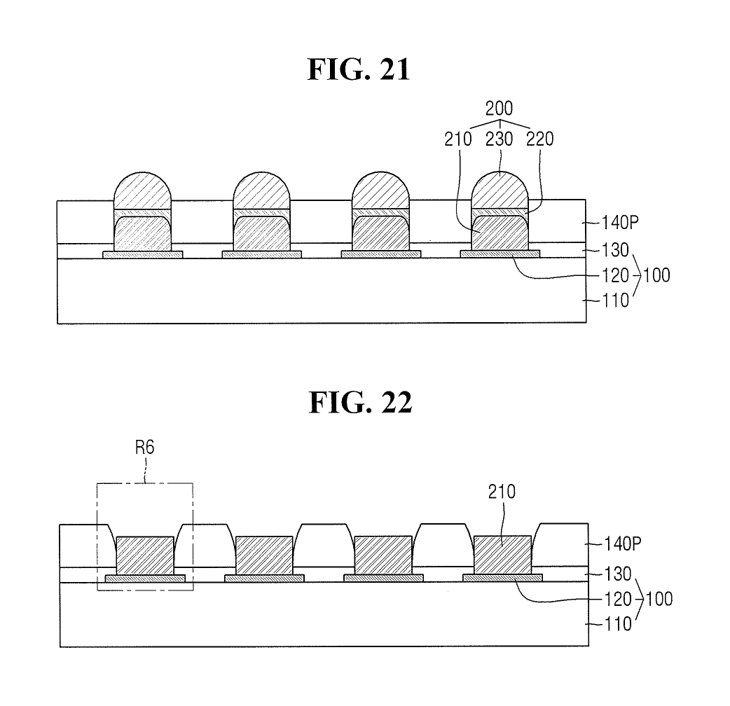

Referring to FIG. 21, a first solder ball 230 is formed on the second conductive pattern 220.

A lower portion of the first solder ball 230 may fill part of the second opening O2 that is not filled with the first and second conductive patterns 210 and 220. Accordingly, the sidewalls of the lower portion of the first solder ball 230 may be defined by the sidewalls of the chip insulating film 130 or the sidewalls of the resist pattern 140P.

The first solder ball 230 may include a solder material. For example, the first solder ball 230 may include at least one of Pb, Sn, In, Bi, Sb, Ag, and an alloy thereof. For example, the first solder ball 230 may be formed through electroplating.

Thereafter, referring to FIGS. 1 and 2, the resist pattern 140P is removed.

The resist pattern 140P may be removed by, for example, wet etching.

Thereafter, referring to FIGS. 9 and 10, the semiconductor chip 100 is mounted on the substrate 300.

The semiconductor chip 100 and the substrate 300 may be electrically connected by the chip bump 200. The mounting of the semiconductor chip 100 on the substrate 300 may be performed by, for example, soldering.

In this manner, a semiconductor package according to some example embodiments of the present disclosure may be fabricated.

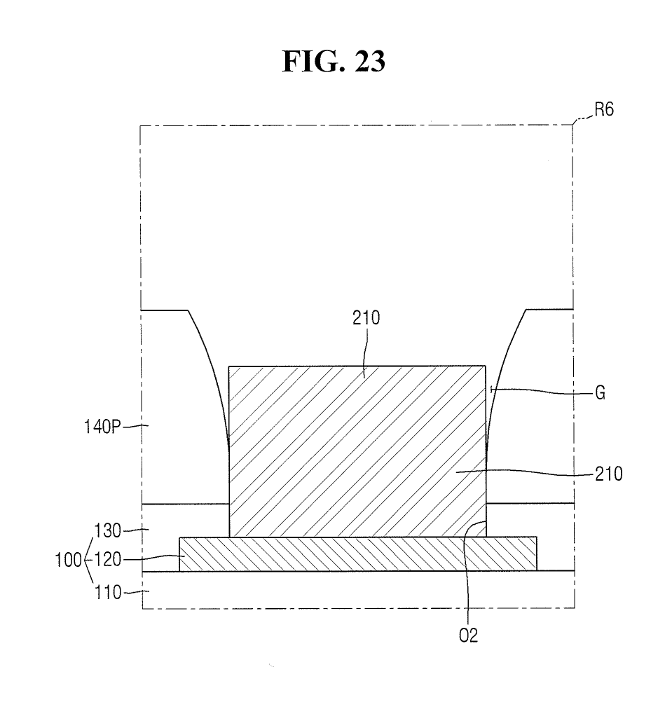

FIGS. 22 through 27 illustrate intermediate steps of a method of fabricating a semiconductor package according to some example embodiments of the present disclosure. For clarity, any redundant descriptions of the example embodiments of FIGS. I through 21 may be omitted. For example, FIGS. 22 and 23 illustrate steps that are performed after the steps described above with reference to FIGS. 15 and 16.

Referring to FIGS. 22 and 23, a resist pattern 140P is contracted. For example, FIG. 23 is an enlarged view of a sixth region R6 of FIG. 22.

For example, the resist pattern 140P may be contracted by performing heating and cooling. For example, the structure illustrated in FIGS. 15 and 16 may be heated by being immersed in a first solution or liquid at a temperature of about 40° C. to about 60° C., and may then be cooled by being immersed in a second solution or liquid at a temperature of about 0° C. to about 10° C. The first and second solutions or liquids may include or may be deionized water (DIW). In this manner, the resist pattern 140P may be contracted.

In some example embodiments, the resist pattern 140P may be contracted so as to form gaps G between a first conductive pattern 210 and the resist pattern 140P. For example, parts of the sidewalls of the resist pattern 140P that are placed in contact with the sidewalls of the upper portion of the first conductive pattern 210 may be peeled off, and as a result, the gaps G may be formed between the first conductive pattern 210 and the resist pattern 140P.

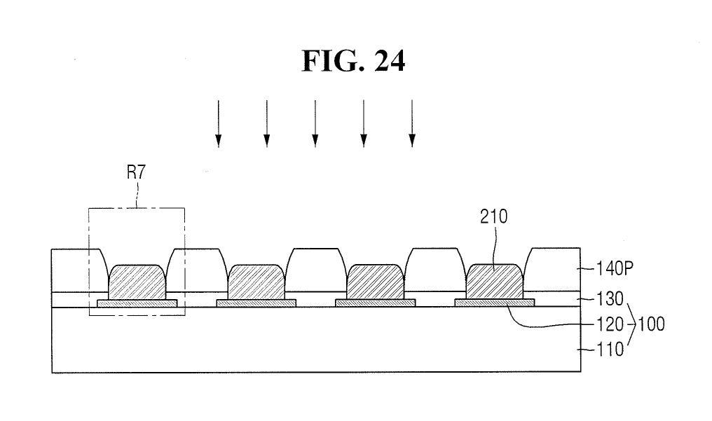

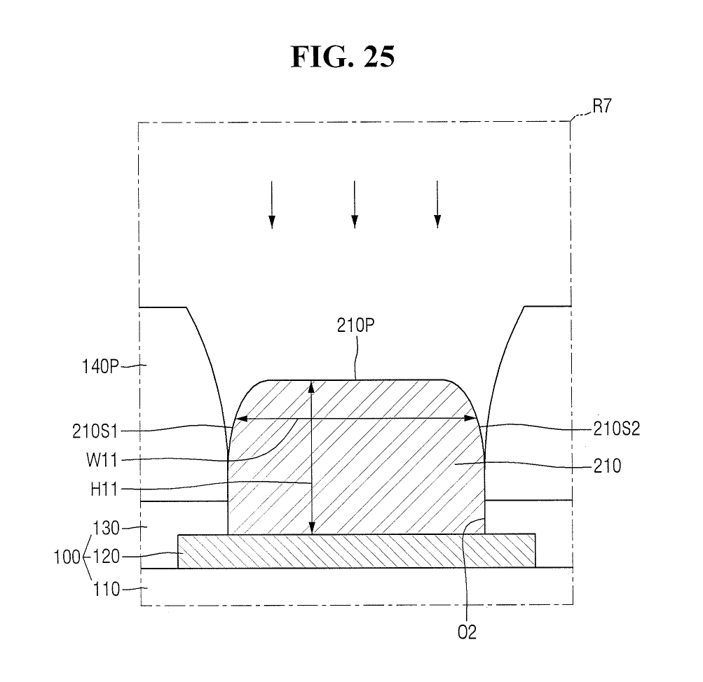

Referring to FIGS. 24 and 25, chemical etching is performed on the first conductive pattern 210. For example, FIG. 25 is an enlarged view of a seventh region R7 of FIG. 24.

For example, a chemical etching operation may be performed to selectively etch the first conductive pattern 210. For example, in a case where the first conductive pattern 210 includes Cu, the chemical etching operation may be performed using an etchant having a high etching selectivity to Cu.

During the chemical etching operation, the etchant may infiltrate into the boundaries between the first conductive pattern 210 and the resist pattern 140P. For example, the etchant may easily infiltrate into the boundaries between the first conductive pattern 210 and the resist pattern 140P through the gaps G of FIG. 24.

The chemical etching operation may be substantially the same as that described above with reference to FIGS. 17 and 18, and thus, a detailed description thereof will not be repeated.

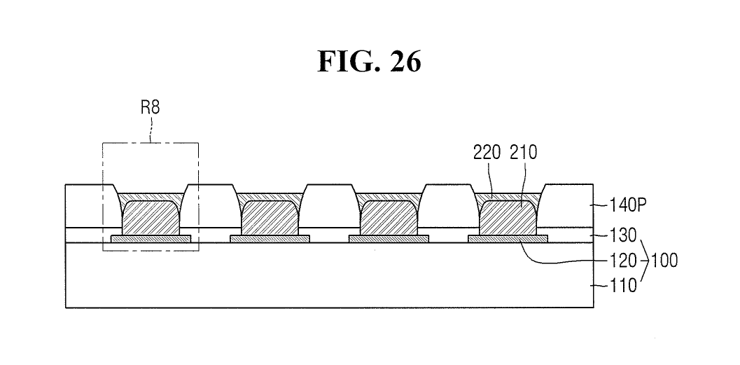

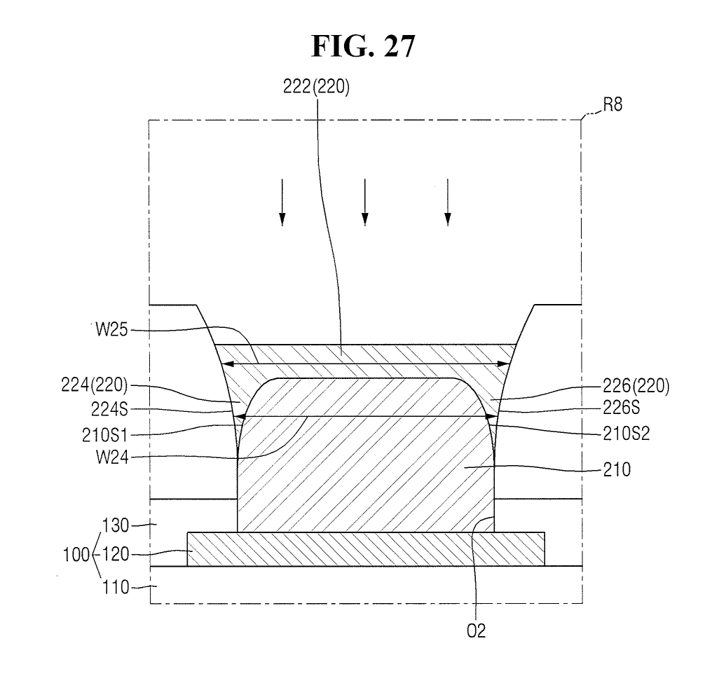

Referring to FIGS. 26 and 27, a second conductive pattern 220 is formed on the first conductive pattern 210. For example, FIG. 27 is an enlarged view of an eighth region R8 of FIG. 26.

For example, the second conductive pattern 220 may be formed to extend along the top surface of the first conductive pattern 210. Accordingly, the second conductive pattern 220 may be formed to include a first protruding portion 224, a second protruding portion 226, and a flat portion 222.

In some example embodiments, the second conductive pattern 220 may be formed to fill part of the second opening O2 that is not filled with the first conductive pattern 210. Accordingly, the sidewalls of the second conductive pattern 220 may be defined by the sidewalls of a chip insulating film 130 or the sidewalls of the resist pattern 140P.

As a result, the second conductive pattern 220 may be formed to have a width gradually increasing away from the top surface of a semiconductor substrate 110.

For example, the distance between a first outer sidewall 224S of the first protruding portion 224 and a second outer sidewall 226S of the second protruding portion 226, i.e., a seventh width W24, may increase away from the top surface of the semiconductor substrate 110. Also, the distance between both sidewalls of the flat portion 222, i.e., an eighth width W25, may increase away from the top surface of the semiconductor substrate 110. The eighth width W25 of the second conductive pattern 220 may be larger than the seventh width W24 of the second conductive pattern 220.

Thereafter, similarly to what has been described above with reference to FIG. 21, a first solder ball 230 is formed on the second conductive pattern 220. Thereafter, similarly to what has been described above with reference to FIGS. 1 and 2, the resist pattern 140P is removed. Thereafter, similarly to what has been described above with reference to FIGS. 9 and 10, a semiconductor chip 100 is mounted on a substrate 300.

By way of summation and review, research has been conducted to develop a flip chip bonding method that is highly reliable, simple, and convenient for the fabrication of a semiconductor package.

As described above, embodiments relate to a semiconductor package having chip bumps and a method of fabricating the semiconductor package. Embodiments may provide a semiconductor package with improved product reliability. Embodiments may provide a method of fabricating a semiconductor package with improved product reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a semiconductor substrate;
a first conductive pattern on the semiconductor substrate, a top surface of the first conductive pattern including a first inclined surface and a second inclined surface that are inclined with respect to a top surface of the semiconductor substrate, and a distance between the first and second inclined surfaces decreasing away from the top surface of the semiconductor substrate;
a second conductive pattern extending along the top surface of the first conductive pattern; and
a solder ball disposed on the second conductive pattern.

2. The semiconductor package as claimed in claim 1, wherein the first and second inclined surfaces extend from opposing sidewalls of the first conductive pattern, respectively.

3. The semiconductor package as claimed in claim 1, wherein the first and second inclined surfaces are upwardly convex.

4. The semiconductor package as claimed in claim 1, wherein the first conductive pattern is not in direct contact with the solder ball.

5. The semiconductor package as claimed in claim 1, wherein a width of the second conductive pattern increases away from the top surface of the semiconductor substrate.

6. The semiconductor package as claimed in claim 1, wherein a width of a bottom surface of the first conductive pattern is less than a width of a top surface of the second conductive pattern.

7. The semiconductor package as claimed in claim 1, wherein a lowermost surface of the first conductive pattern and a lowermost surface of the second conductive pattern are disposed substantially on the same plane.

8. The semiconductor package as claimed in claim 1, further comprising:
a chip pad on the semiconductor substrate; and
a chip insulating film, the chip insulating film including an opening that partially exposes a top surface of the chip pad,
wherein the first conductive pattern fills the opening and is in contact with the chip pad.

9. The semiconductor package as claimed in claim 8, wherein a width of at least a part of the first conductive pattern is larger than a width of the opening.

10. The semiconductor package as claimed in claim 1, further comprising an intermetallic compound (IMC) film between the second conductive pattern and the solder ball, the IMC film including an IMC between the second conductive pattern and the solder ball.

11. The semiconductor package as claimed in claim 1, wherein
the first conductive pattern includes copper, and
the second conductive pattern includes nickel.

12. A semiconductor package, comprising:
a semiconductor substrate;
a first conductive pattern on the semiconductor substrate, the first conductive pattern having a top surface that includes a first inclined surface and a second inclined surface that are inclined with respect to a top surface of the semiconductor substrate;
a second conductive pattern on the first conductive pattern, the second conductive pattern including a first protruding portion, which extends along the first inclined surface, and a second protruding portion, which extends along the second inclined surface, a width of the first protruding portion and a width of the second protruding portion increasing away from the top surface of the semiconductor substrate; and
a solder ball on the second conductive pattern.

13. The semiconductor package as claimed in claim 12, wherein the second conductive pattern further includes a flat portion that connects the first and second protruding portions.

14. The semiconductor package as claimed in claim 13, wherein a width of the flat portion increases away from the top surface of the semiconductor substrate.

15. The semiconductor package as claimed in claim 13, wherein a top surface of the flat portion is substantially parallel to the top surface of the semiconductor substrate.

16. The semiconductor package as claimed in claim 13, wherein a top surface of the flat portion is upwardly convex.

17. The semiconductor package as claimed in claim 12, wherein a distance between an outer sidewall of the first protruding portion and an outer sidewall of the second protruding portion increases away from the top surface of the semiconductor substrate.

18. A semiconductor package, comprising:
a substrate for the semiconductor package;
a chip bump disposed on the substrate;
a semiconductor chip disposed on the chip bump; and
a first mold film disposed between the substrate and the semiconductor chip and surrounding the chip bump, wherein:
the chip bump includes a first conductive pattern, which is in contact with the semiconductor chip, a solder ball, which is in contact with the substrate, and a second conductive pattern, which is between the first conductive pattern and the solder ball, and
a distance between a bottom surface of the first conductive pattern and a bottom surface of the second conductive pattern decreases away from the first mold film.

19. The semiconductor package as claimed in claim 18, wherein a distance between a top surface of the first conductive pattern and a top surface of the second conductive pattern increases away from the first mold film.

20. The semiconductor package as claimed in claim 18, further comprising a second mold film on the substrate, the second mold film surrounding the semiconductor chip and the first mold film.
